(19) United States
(12) Patent Application Publication
(10) Pub. No.: US 2003/0222351 A1
(43) Pub. Date: Dec. 4, 2003

(54) Semiconductor device with thick interconnections free of dishing and erosion, and method of manufacturing such semiconductor device

(75) Inventor: Takehiro Aritoku, Kanagawa (JP)

Correspondence Address: YOUNG & THOMPSON, 745 SOUTH 23RD STREET 2ND FLOOR, ARLINGTON, VA, 22202

(73) Assignee: NEC ELECTRONICS CORPORATION, Kanagawa (JP)

(21) Appl. No.: 10/442,048

(22) Filed: May 21, 2003

(30) Foreign Application Priority Data
Jun. 4, 2002 (JP) 2002-162458

(51) Int. Cl. H01L 23/48

(52) U.S. Cl. 257/758

(57) ABSTRACT

A semiconductor device has an insulating film, a group of narrow grooves defined in the insulating film, the narrow grooves having a first interconnection width, and a group of wide grooves defined in the insulating film and having a second interconnection width. A plated film is formed in the narrow grooves and the wide grooves and on the insulating film. The second interconnection width is greater than the first interconnection width and limited to a range of widths subject to a bottom-up effect. Because the width of the second interconnection width is limited to the range of widths subject to the bottom-up effect, when the plated film is formed in the narrow grooves and the wide grooves, the plated film has a relatively large thickness over the wide grooves. Therefore, when the plated film is subsequently removed by CMP (Chemical Mechanical Plating), the plated film in the wide grooves is free of dishing and erosion.

### BACKGROUND OF THE INVENTION

1. Field of the Invention

The present invention relates to a semiconductor device having a group of narrow grooves and a group of wide grooves which are defined in an insulating film and a plated film of copper or the like which is formed in the wide grooves and the narrow grooves and on the insulating film, and a method of manufacturing such a semiconductor device.

2. Description of the Related Art

In recent years, it has become more important to use groove interconnections of copper or the like as an element for achieving high-performance interconnections on semiconductor devices.

Heretofore, as shown in FIGS. 2 and 3 of the accompanying drawings, it has been customary to form grooves as interconnection regions in insulating films 40, 50, grow barrier metal and seed copper layers 41, 51 in the grooves by way of sputtering, deposit plated films 42, 52 of copper or the like on layers 41, 51 by way of plating, and removing unwanted copper protrusions from the grooves by way of a CMP (Chemical Mechanical Polishing) process, thus producing groove interconnections of copper.

It is known in the art that according to the CMP process, relatively wide interconnections or regions where such relatively wide interconnections are closely present are polished excessively, causing dishing (see FIG. 2) or erosion (see FIG. 3) which tends to result in an increased interconnection resistance.

Usually, it has been attempted to limit interconnection widths to avoid dishing and also to keep wide interconnections widely spaced from each other to avoid erosion.

According to the conventional process described above, however, wide interconnections still have a large width though their width is limited, and are liable to suffer a certain degree of dishing. As a result, those wide interconnections have such a high resistance that narrow and wide interconnections have different sheet resistances [Ω/□]. The sheet resistance of a wide interconnection which is suffering dishing varies in a range depending on the degree of dishing. Therefore, circuit interconnections have to be designed taking into account a range of variations which the sheet resistance of wide interconnections can be subject to. The range of sheet resistance variations which need to be taken into consideration presents a substantial obstacle to efforts to produce higher-speed LSI (large-scale integration) circuits.

The increased spacing provided between wide interconnections for preventing erosion is detrimental to efforts to design higher-density LSI circuits.

### SUMMARY OF THE INVENTION

It is an object of the present invention to provide a semiconductor device which can be designed with a reduced possible margin or range of resistance variations and can also be designed for higher-speed configurations by reducing the width and spacing of wide interconnections and limiting them to a range for preventing dishing and erosion which is determined from the fabrication process, and a method of manufacturing such a semiconductor device.

Another object of the present invention is to provide a semiconductor device which has wide interconnections spaced as closely as possible and hence can be designed for a highly integrated configuration, and a method of manufacturing such a semiconductor device.

According to an aspect of the present invention, there is provided a semiconductor device comprising an insulating film, a group of narrow grooves defined in the insulating film, the narrow grooves having a first interconnection width, a group of wide grooves defined in the insulating film and having a second interconnection width greater than the first interconnection width, and a plated film formed in the narrow grooves and the wide grooves and on the insulating film. The second interconnection width is greater than the first interconnection width and limited to a range of widths subject to a bottom-up effect.

Since the width of the second interconnection width is limited to the range of widths subject to the bottom-up effect, when the plated film is formed in the narrow grooves and the wide grooves, the plated film has a relatively large thickness over the wide grooves. Therefore, when the plated film is subsequently removed by CMP, the plated film in the wide grooves is free of dishing and erosion.

The bottom-up effect represents a phenomenon in which the plated film is formed to an increased thickness on steps of the grooves.

Preferably, the insulating film has a flat region free of grooves, and the plating film has a surface which is of substantially the same height over the group of wide grooves, the group of narrow grooves, and the flat region. With this arrangement, as the plated film over the group of wide grooves, the group of narrow grooves, and the flat region is polished to substantially the same depth, it is made free of dishing or erosion.

Preferably, the plated film has a resistance per unit area independent of the second interconnection width because the second interconnection width is limited to the range of widths subject to the bottom-up effect.

Preferably, the spacing between the wide grooves is set to a minimum distance because the second interconnection width is limited to the range of widths subject to the bottom-up effect.

The plated film is preferably formed of copper, and at least either a barrier metal layer or a seed layer may be interposed between the insulating film and the plated film.

The second interconnection width is preferably 4 μm at maximum.

According to another aspect of the present invention, there is provided a method of manufacturing a semiconductor device having an insulating film, comprising the steps of defining in an insulating film a group of narrow grooves having a first interconnection width and a group of wide grooves having a second interconnection width greater than the first interconnection width, forming a plated film in the narrow grooves and the wide grooves and on the insulating film according to plating, with the wide grooves being limited to a range of widths subject to a bottom-up effect, and removing protrusions of the plated film from the narrow and wide grooves, leaving a group of wide interconnections in the group of wide grooves and a group of narrow interconnections in the group of narrow grooves.

In the above method, the bottom-up effect represents a phenomenon in which the plated film is formed to an increased thickness on steps of the grooves.

Preferably, the method further comprises the step of forming a flat region free of grooves on the insulating film, the plating film having a surface which is of substantially the same height over the group of wide grooves, the group of narrow grooves, and the flat region.

Preferably, the plated film over the group of wide grooves, the group of narrow grooves, and the flat region is polished to substantially the same depth by the chemical mechanical polishing.

The plated film over the group of wide grooves, the group of narrow grooves, and the flat region is preferably made free of dishing or erosion by being polished to substantially the same depth.

The spacing between the wide grooves is preferably set to a minimum distance by making the plated film free of erosion.

The plated film preferably has a resistance per unit area independent of the second interconnection width because the second interconnection width is limited to the range of widths subject to the bottom-up effect.

Preferably, the plated film is formed of copper, and the method further comprises the step of forming at least either a barrier metal layer or a seed layer between the insulating film and the plated film.

The above and other objects, features, and advantages of the present invention will become apparent from the following description with reference to the accompanying drawings which illustrate an example of the present invention.

### BRIEF DESCRIPTION OF THE DRAWINGS

FIG. 1 is a fragmentary cross-sectional view illustrative of a bottom-up effect;

FIG. 2 is a fragmentary cross-sectional view illustrative of an excessive polishing phenomenon due to dishing;

FIG. 3 is a fragmentary cross-sectional view illustrative of an excessive polishing phenomenon due to erosion;

FIG. 4 is a fragmentary cross-sectional view of a semiconductor device according to an embodiment of the present invention; and

FIG. 5 is a fragmentary cross-sectional view of the semiconductor device according to the embodiment of the present invention.

### DESCRIPTION OF THE PREFERRED EMBODIMENT

An embodiment of the present invention resides in that a semiconductor device has groove interconnections including wide interconnections having a width which is limited to a range of widths subject to a bottom-up effect that occurs in a plating process in which grooves are filled, so that the semiconductor device can be designed with its resistance per unit area being independent of the interconnection width.

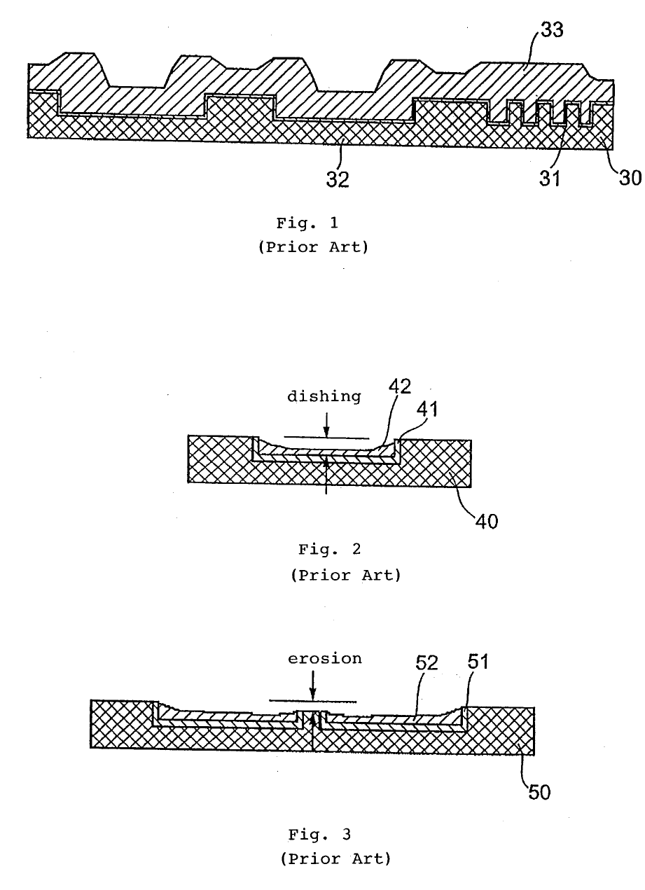

The bottom-up effect referred to above will be described below with reference to FIG. 1.

As shown in FIG. 1, a group of narrow grooves 31 and a group of wide grooves 32 are defined in insulating film 30, and plated film 33 of copper or the like is formed in narrow grooves 31 and wide grooves 32 and on insulating film 30.

The bottom-up effect refers to a phenomenon in which a plated film is grown to an increased thickness on groove ends (steps). Specifically, as shown in FIG. 1, plated film 33 is grown to a relatively large thickness over narrow grooves 31 and steps of wide grooves 32.

The embodiment of the present invention will be described below with reference to FIGS. 4 and 5. As shown in FIG. 4, a group of narrow grooves 2 and a group of wide grooves 3 are defined in insulating film 1, and plated film 6 of copper or the like is formed in narrow grooves 2 and wide grooves 3 and on insulating film 1. At least one of barrier metal layer 4 and seed copper layer 5 is formed between insulating film 1 and plated film 6.

According to the embodiment of the present invention, the wide grooves have a width limited to a range of widths subject to the bottom-up effect described above. Therefore, the height of the surface of plated film 6 remains substantially the same over the group of narrow grooves 2, the group of wide grooves 3, and flat region 7 free of grooves.

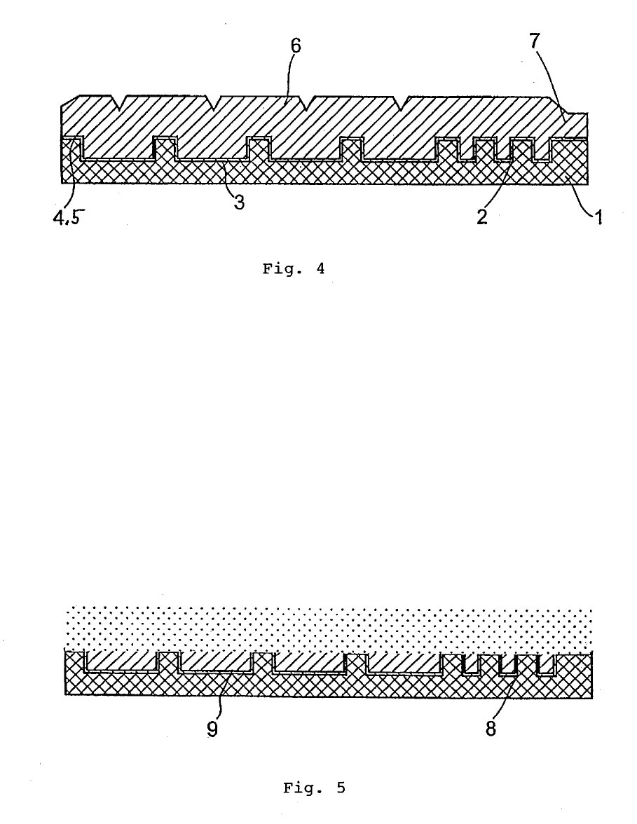

As shown in FIG. 5, when plated film 6 of copper or the like is subjected to CMP in a subsequent process, plated film 6 is polished to substantially the same depth over those various regions, without causing dishing (see FIG. 2) or erosion (see FIG. 3). Since no erosion takes place, the spacing between wide grooves 3 can be set to a minimum distance.

If the wide grooves have a width not subject to the bottom-up effect, as with the conventional arrangement, then as shown in FIG. 1, the surface of plated film 33 is progressively lower toward the center of each wide groove 32. When the surface of plated film 33 is polished, it necessarily suffers dishing or erosion. Therefore, circuit interconnections need to be designed taking into account an increase in the resistance of the wide grooves due to dishing, and the spacing between wide grooves 32 has to be increased to prevent undue erosion.

A comparison between FIG. 1 and FIGS. 4 and 5 indicates that although the sum of the interconnection widths of the group of wide grooves 3 and the group of narrow grooves 2 in the structure shown in FIGS. 4 and 5 is substantially the same as the sum of the interconnection widths in the structure shown in FIG. 1, the width of wide grooves 3 and the spacing between wide grooves 3 in the structure shown in FIGS. 4 and 5 are smaller than those in the structure shown in FIG. 1. Consequently, the structure shown in FIGS. 4 and 5 makes it possible to fabricate semiconductor devices such as LSI circuits or the like in a more highly integrated fashion than the conventional structure shown in FIG. 1.

Embodiment:

The embodiment of the present invention will be described in detail below with reference to FIGS. 4 and 5.

A group of narrow grooves 2 each having a depth of about 4000 Å and a groove of wide grooves 3 each having a maximum width of about 4 μm are formed in insulating film 1 by lithography and etching.

Then, at least one of barrier metal layer 4 and seed copper layer 5 is deposited to a thickness of about 1000 Å on the entire surface of insulating film 1. Thereafter, plated film 6 is formed to a thickness of about 7000 Å by a copper plating process. According to the conventional arrangement, the bottom-up effect occurs on the steps of the grooves to increase the thickness of plated film 6 on the steps. According to the embodiment of the present invention, since the wide grooves have a width limited to a range of widths subject to the bottom-up effect. Therefore, the configuration shown in FIG. 4 is achieved. In the configuration shown in FIG. 4, the height of the surface of plated film 6 remains substantially the same over the group of narrow grooves 2, the group of wide grooves 3, and flat region 7 free of grooves.

Then, protrusions projecting from the grooves are removed by way of CMP, thus producing groove interconnections including a group of narrow groove interconnections 8 and a group of wide groove interconnections 9.

Since the thickness of copper to be removed by CMP is the same in any pattern areas, no dishing or erosion occurs. As no erosion takes place, the spacing between wide grooves can be set to a minimum distance.

Inasmuch as wide groove interconnections 9 have a width limited to a range of widths subject to the bottom-up effect, the resistance per unit area of plated film 6 over wide groove interconnections 9 does not depend on the width of wide grooves 9 in particular. More specifically, as shown in FIG. 5, as wide grooves 3 are filled up with plated film 5, the thickness of wide groove interconnections 9 is constant. Consequently, even if wide groove interconnections 9 have different design widths, the resistance per unit area of plated film 6 over wide groove interconnections 9 remains constant. Stated otherwise, the resistance per unit area of plated film 6 over wide groove interconnections 9 does not depend on the width of wide groove interconnections 9.

The range of widths of wide groove interconnections 9 which is subject to the bottom-up effect depends mostly on the ability of the plating solution which is used in the plating process to form plated film 6.

While a preferred embodiment of the present invention has been described using specific terms, such description is for illustrative purposes only, and it is to be understood that changes and variations may be made without departing from the spirit or scope of the following claims.

What is claimed is:

1. A semiconductor device comprising:
an insulating film;
a group of narrow grooves defined in said insulating film, said narrow grooves having a first interconnection width;
a group of wide grooves defined in said insulating film, said wide grooves having a second interconnection width greater than said first interconnection width and limited to a range of widths subject to a bottom-up effect; and
a plated film formed in said narrow grooves and said wide grooves and on said insulating film.

2. A semiconductor device according to claim 1, wherein said bottom-up effect represents a phenomenon in which said plated film is formed to an increased thickness on steps of said grooves.

3. A semiconductor device according to claim 1, wherein said insulating film has a flat region free of grooves, said plating film having a surface which is of substantially the same height over said group of wide grooves, said group of narrow grooves, and said flat region.

4. A semiconductor device according to claim 1, wherein said plated film has a resistance per unit area independent of said second interconnection width because said second interconnection width is limited to the range of widths subject to the bottom-up effect.

5. A semiconductor device according to claim 1, wherein the spacing between said wide grooves is set to a minimum distance because said second interconnection width is limited to the range of widths subject to the bottom-up effect.

6. A semiconductor device according to claim 1, wherein said plated film is formed of copper, further comprising at least either a barrier metal layer or a seed layer interposed between said insulating film and said plated film.

7. A semiconductor device according to claim 1, wherein said second interconnection width is 4 μm at maximum.

8. A method of manufacturing a semiconductor device having an insulating film, comprising the steps of:
defining in an insulating film a group of narrow grooves having a first interconnection width and a group of wide grooves having a second interconnection width greater than said first interconnection width, according lithography and etching;
forming a plated film in said narrow grooves and said wide grooves and on said insulating film according to plating, with said wide grooves being limited to a range of widths subject to a bottom-up effect; and
removing protrusions of said plated film from said narrow and wide grooves according to chemical mechanical polishing, leaving a group of wide interconnections in said group of wide grooves and a group of narrow interconnections in said group of narrow grooves.

9. A method according to claim 8, wherein said bottom-up effect represents a phenomenon in which said plated film is formed to an increased thickness on steps of said grooves.

10. A method according to claim 8, further comprising the step of:
forming a flat region free of grooves on said insulating film, said plating film having a surface which is of substantially the same height over said group of wide grooves, said group of narrow grooves, and said flat region.

11. A method according to claim 10, wherein said plated film over said group of wide grooves, said group of narrow grooves, and said flat region is polished to substantially the same depth by the chemical mechanical polishing.

12. A method according to claim 11, wherein said plated film over said group of wide grooves, said group of narrow grooves, and said flat region is made free of dishing or erosion by being polished to substantially the same depth.

13. A method according to claim 12, wherein the spacing between said wide grooves is set to a minimum distance by making said plated film free of erosion.

14. A method according to claim 8, wherein said plated film has a resistance per unit area independent of said second interconnection width because said second interconnection width is limited to the range of widths subject to the bottom-up effect.

15. A method according to claim 8, wherein said plated film is formed of copper, said method further comprising the step of:
forming at least either a barrier metal layer or a seed layer between said insulating film and said plated film.
